(19) United States
(12) Patent Application Publication
(10) Pub. No.: US 2025/0006562 A1
(43) Pub. Date: Jan. 2, 2025

(54) METHOD FOR OPTIMIZING LAYOUT PATTERN AND SEMICONDUCTOR WAFER

(71) Applicant: Winbond Electronics Corp., Taichung City (TW)

(72) Inventors: Chun-Hung Lin, Taichung City (TW); Hsin-Hung Chou, Taichung City (TW); Kao-Tsair Tsai, Taichung City (TW)

(73) Assignee: Winbond Electronics Corp., Taichung City (TW)

(21) Appl. No.: 18/754,181

(22) Filed: Jun. 26, 2024

(30) Foreign Application Priority Data
Jun. 27, 2023 (TW) 112123938

(51) Int. Cl. H01L 21/66; G01R 31/28; G03F 7/00

(52) U.S. Cl. CPC H01L 22/12; G01R 31/2831; G03F 7/70441; G03F 7/705

(57) ABSTRACT

A layout optimization method and a semiconductor wafer are provided. The method includes: generating adjusted patterns corresponding to a first layout pattern; generating a layout optimization test group according to the adjusted patterns, wherein the layout optimization test group includes first and second clusters of test pattern arrays, the first cluster include first test pattern arrays in accordance with one of the adjusted patterns and different from one another in terms of capacity, and the second cluster include second test pattern arrays in accordance with another one of the adjusted patterns and different from one another in terms of capacity; forming the layout optimization test group on a wafer; performing an electrical inspection on the first and second pattern arrays, and determining a best manufacturing solution from the adjusted patterns according to the electrical inspection.

### CROSS-REFERENCE TO RELATED APPLICATION

This application claims the priority benefit of Taiwan application serial no. 112123938, filed on Jun. 27, 2023. The entirety of the above-mentioned patent application is hereby incorporated by reference herein and made a part of this specification.

### BACKGROUND

### Technical Field

The present disclosure relates to a layout pattern designing method for mass production of semiconductor wafers, and more particularly, to a method for optimizing layout pattern and a semiconductor wafer.

### Description of Related Art

Along with development of semiconductor industry, electronic products have become smaller in size and greater in integrated circuit density. In order to fulfill the continuous miniaturization and higher integration level, feature size (e.g., critical line width or pitch) of integrated circuit is gradually scaled down. The scaling of feature size results in inconsistency between designed patterns and actual patterns resulted from lithography process, and such inconsistency may be caused by optical proximity effect (OPE). Due to pattern distortion, short circuit, open circuit or other electrical issues may be resulted in the manufactured integrated circuit.

In general, test patterns as part of original design patterns are formed in chip regions of wafer, and are subjected to chip probe (CP) test, such that whether if the original design patterns would result in electrical issues can be evaluated. However, it takes a long time from pattern design to the completion of the CP test. If it is discovered that the design patterns needs to be adjusted after the CP test, it will be detrimental to the development efficiency of the semiconductor device. Moreover, if there is an abnormality in the production of the front (underlying) layer of the test patterns, it will easily interfere with the results of the CP test, leading to inaccurate inference results. Further, forming test patterns in chip regions of wafer would occupy valuable estate in chip regions, and it is disadvantageous for pursuing higher integration level.

As another approach, test keys or test element groups (TEGs) may be disposed in scribe line region of wafer, for checking defects resulted during manufacturing. Specifically, while devices are manufactured in chip regions in various process steps, test keys or TEGs are formed in scribe line region, and various properties of the test keys or TEGs are evaluated by testing apparatus, so as to monitor the devices in chip regions and to ensure process yield. However, test keys or TEGs usually include a single type of test pattern (e.g., a comb pattern), which might not be indicative for other types of patterns in chip regions.

Further, current research and development process mainly rely on experience of designers. A long process of trial-and-error may be required for optimizing layout patterns.

### SUMMARY

Therefore, an improved method is required, for optimizing layout pattern by accurately finding a best solution for each lithography hotspot without delaying development process.

In an aspect of the present disclosure, a method for optimizing layout pattern comprises: generating adjusted patterns corresponding to a first layout pattern; generating a layout optimization test group according to the adjusted patterns, wherein the layout optimization test group comprises a first cluster of test pattern arrays and a second cluster of test pattern arrays, the first cluster of test pattern arrays comprise first test pattern arrays in accordance with one of the adjusted patterns and different from one another in terms of capacity, and the second cluster of test pattern arrays comprise second test pattern arrays in accordance with another one of the adjusted patterns and different from one another in terms of capacity; forming the layout optimization test group on a wafer; performing an electrical inspection on the first test pattern arrays and the second test pattern arrays, and determining a best manufacturing solution from the adjusted patterns according to a result of the electrical inspection; and determining a second layout pattern to be formed on chip regions of the wafer according to the best manufacturing solution.

In another aspect of the present disclosure, a semiconductor wafer is provided. The semiconductor wafer comprises: an integrated circuit, formed in a chip region; and a layout optimization test group, formed in a scribe line region, wherein the layout optimization group comprises a first cluster of test pattern arrays and a second cluster of test pattern arrays, the first cluster of test pattern arrays comprises first test pattern arrays in accordance with a first adjusted pattern and different from one another in terms of capacity, and the second cluster of test pattern arrays comprises second test pattern arrays in accordance with a second adjusted pattern and different with one another in terms of capacity.

As compared to relying on experience to adjust layout pattern and modifying layout pattern via trial-and-error manner, the pattern optimization process provided in the present disclosure is much shorter in time, and more promising yield can be ensured. Further, when manufacturing process is adjusted, whether if the current layout pattern needs to be modified can be determined by placing a layout optimization test group in a scribe line region of a wafer and executing electrical inspection on the layout optimization test group. In this way, development of a new process can be shortened. Further, in some embodiments, the electrical inspection performed on the layout optimization test group does not have to wait until entire wafer process is finished. Instead, the electrical inspection can be performed right after formation of the layout optimization test group. Therefore, the test result can be more indicative, and a shorter layout pattern optimization process can be resulted.

### BRIEF DESCRIPTION OF THE DRAWINGS

FIG. 1 is a flow diagram illustrating a method for adjusting layout patterns, according to some embodiments of the present disclosure.

FIG. 2 is a schematic plan view exemplarily illustrating chip regions and a scribe line region in a wafer.

FIG. 3A is a schematic plan view illustrating a featured pattern array that might cause difficulties in lithography.

FIG. 3B is a schematic plan view illustrating another featured pattern array that might cause difficulties in lithography.

FIG. 4A through FIG. 4C are schematic plan views illustrating adjustment schemes for the featured pattern array shown in FIG. 3A, according to some embodiments of the present disclosure.

FIG. 5 is a schematic plan view illustrating a cluster of test pattern arrays for one of the adjustment schemes.

FIG. 6 is a schematic plan view illustrating a wafer formed with a first layout pattern.

FIG. 7A through FIG. 7D presents electrical trend line each showing WAT results with respect to capacities of a corresponding cluster of test pattern arrays.

FIG. 8 is a schematic plan view illustrating a semiconductor chip singulated from the wafer, according to some embodiments of the present disclosure.

### DESCRIPTION OF THE EMBODIMENTS

A method for optimizing layout pattern according to embodiments of the present disclosure includes disposing at least one layout optimization test group in a scribe line region of a wafer for optimizing layout patterns, and disposing the optimized layout pattern in chip regions of the wafer. The layout optimization test group includes multiple clusters of test pattern arrays. Each cluster is different from other clusters in terms of test pattern design, and each cluster of test pattern arrays includes test pattern arrays formed by the same test pattern but different from one another in terms of capacity (amount). The test pattern in each cluster is a pattern modified from an original pattern, according to a suggested scheme. In some embodiments, the original pattern may be a design pattern or a current layout pattern before process adjustments. The suggested scheme may be obtained by OPC simulation, in this case, the test pattern may be also called as OPC simulation split. By analyzing results of electrical inspection executed on the clusters of test pattern arrays, one of the clusters of test pattern arrays can be selected as a best option, and the optimized layout pattern can be manufactured based on this best option. According to embodiments of the present disclosure, the optimizing process for layout pattern can be shortened. Besides, by placing the layout optimization test group in the scribe line region of the wafer, the production throughput can be increased.

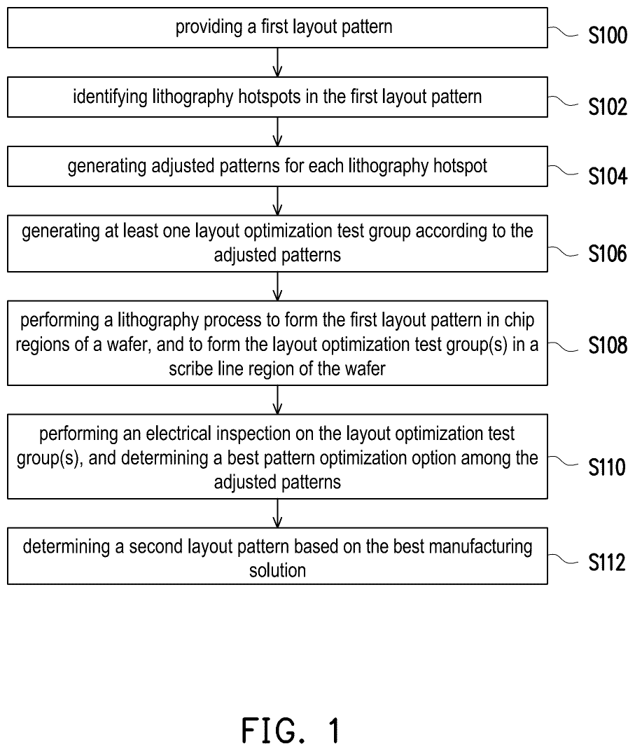

Referring to FIG. 1, the method may begin from a step S100, where a layout pattern to be modified (also referred to as a first layout pattern) is provided. The first layout pattern is designed for forming one of pattern layers of an integrated circuit on a wafer. As an example, the first layout pattern is a pattern layer of a memory array. The first layout pattern has not been optimized yet. Certain portions of the first layout pattern may be special in terms of shape, highly complicated or located in a transition zone between a high-density zone and a low-density zone, and may cause difficulties in photomask design or result in defects in the manufactured pattern layer on the wafer. A best adjustment scheme for optimizing the first layout pattern will be determined in the following steps. The wafer may be a semiconductor wafer (e.g., a silicon wafer) or a semiconductor-on-insulator (SOI) wafer (e.g., a silicon-on-insulator wafer). According to some embodiments, the integrated circuit includes a memory integrated circuit. As examples, the memory integrated circuit may be a flash memory integrated circuit, a dynamic random-access memory (DRAM) integrated circuit or the like. In these embodiments, the first layout pattern may include patterns for forming word lines, bit lines, source lines or another pattern layer in cell regions of the memory integrated circuit. In addition, in some embodiments, the first layout pattern is provided by a computer system, such as an electronic computer-aided design system.

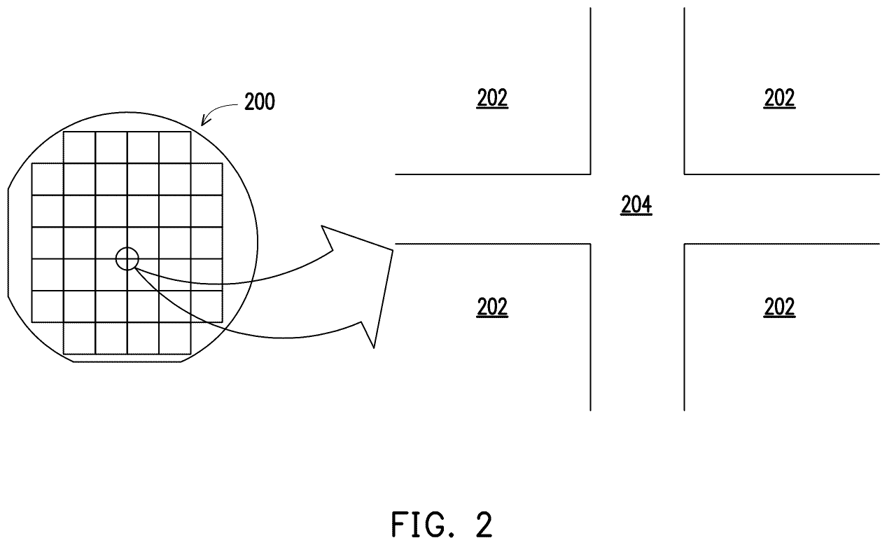

Referring to FIG. 2, a plurality of chip regions 202 and a scribe line region 204 between the chip regions 202 may be defined in the wafer 200. The chip regions 202 may be arranged as an array. The integrated circuit may be formed within the chip regions 202. After manufacturing of the integrated circuit, a singulation process may be performed along the scribe line region 204 during a packaging process, to singulate the chip regions 202 and form a plurality of semiconductor chips.

At a subsequent step S102 shown in FIG. 1, lithography hotspots are identified from the first layout pattern. The lithography hotspots may be special in terms of shape, highly complicated or located in a transition zone between a high-density zone and a low-density zone, and may cause difficulties in lithography. According to some embodiments, an optical proximity correction (OPC) simulation software may be utilized for identifying the lithography hotspots. In these embodiments, the lithography hotspots may include featured pattern arrays formed by repetitive pattern elements.

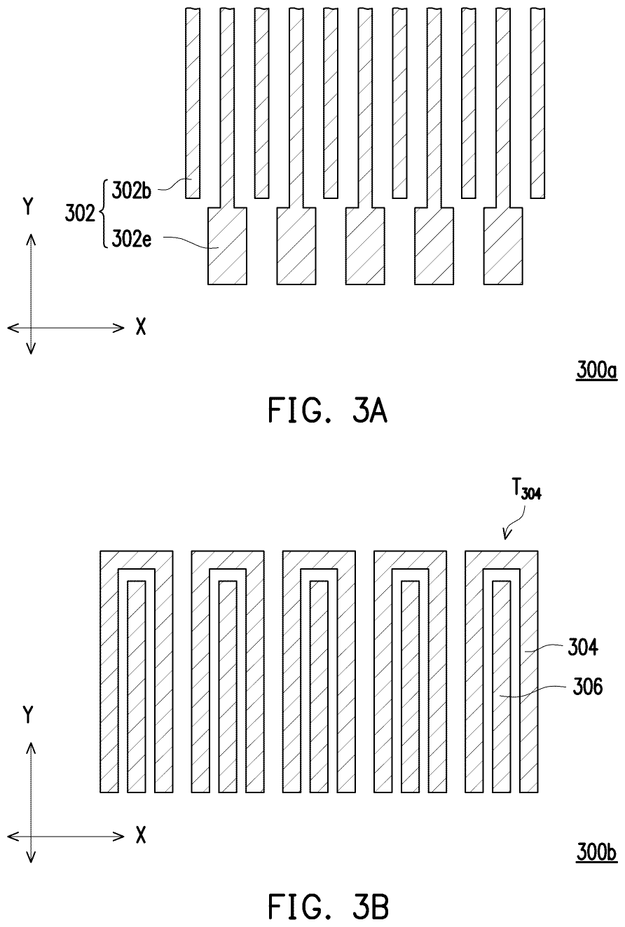

Referring to FIG. 3A, a featured array pattern 300a according to some embodiment of the present disclosure includes multiple lines 302. Each line 302 extends along a direction Y, and the lines 302 are separately arranged along a direction X. In addition, the lines 302 may alternately have extending portions 302e, which can be regarded as a portion of the repetitive pattern elements. The extending portions 302e further extend from body portions 302b of the corresponding lines 302, and are formed in rectangular shape (hammer shape). The extending portion 302e has an initial length-to-width ratio. Inevitably, due to issues such as OPE, the featured array pattern 300a may be transferred (by a lithography process) to the wafer with a certain level of distortion. For instance, the body portions 302b may be excessively divergent toward the extending portions 302e, and sufficient spacing between lines 302 may not be promised. Consequently, raise of resistance-capacitance (RC) delay and/or even shorting between adjacent lines 302 may be resulted.

Referring to FIG. 3B, another featured array pattern 300b according to other embodiments of the present disclosure includes fold lines 304 and straight lines 306. Each fold line 304 has a 180-degree folding T₃₀₄ (in U-shape), and an end portion of each straight line 306 is located at an inner side the folding T₃₀₄ of one of the fold lines 304, so as to be surrounded (by three sides) by this fold line 304. Further, the fold line 304 and the straight line 306 in each pair may be spaced apart, and pairs of the fold lines 304 and the straight lines 306 may be periodically arranged along the direction X. Bridging of the end portions of the straight lines 306 to the fold lines 304 may be resulted when the featured array pattern 300b is transferred to the chip by a lithography process.

It should be appreciated that, the featured array patterns 300a, 300b illustrated in the present disclosure are just two examples. The first layout pattern may include other featured portions that could be identified as the lithography hotspots. The present disclosure is not limited to types, locations and/or shapes of the feature portions.

At a step S104 shown in FIG. 1, adjustment schemes for each lithography hotspot (referred to as adjusted patterns) are provided. In some embodiments, the OPC simulation software are not only operated to identify the lithography hotspots, but also functioned to generate the adjustment schemes for the lithography hotspots. In the illustrated embodiments, multiple adjustment schemes may be generated for a single lithography hotspot.

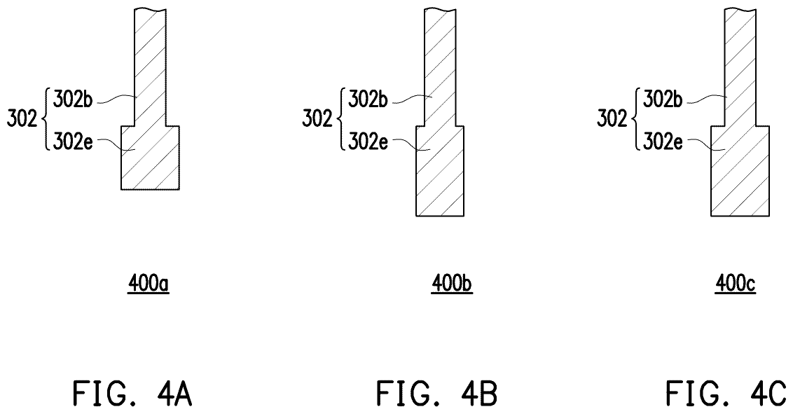

Referring to FIG. 4A through FIG. 4C, in the illustrate embodiments (but not limited to), three adjustment schemes may be obtained for the featured array pattern 300a shown in FIG. 3A, and are referred to as an adjusted pattern 400a, an adjusted pattern 400b and an adjusted pattern 400c. Specifically, at least one adjustment scheme (i.e., at least one adjusted pattern) is obtained by modifying the initial length-to-width ratio of the extending portion 302e of the line 302 in the featured array pattern 300a. Each adjusted pattern is obtained with a modified length-to-width ratio of the extending portion 302e of the line 302, and the adjusted patterns 400a, 400b and 400c are different from one another in terms of the modified length-to-width ratio. For instance, in the illustrated embodiments, a length of the extending portion 302e of the adjusted pattern 400a is identical with the initial length of the extending portion 302e, while a width of the extending portion 302e of the adjusted pattern 400a is greater than the initial width of the extending portion 302e. A length of the extending portion 302e of the adjusted pattern 400b is greater than the initial length of the extending portion 302e, whereas a width of the extending portion 302e of the adjusted pattern 400b is identical with the initial width of the extending portion 302e. A length of the extending portion 302e of the adjusted pattern 400c is greater than the initial length of the extending portion 302e, and a width of the extending portion 302e of the adjusted pattern 400c is greater than the initial width of the extending portion 302e.

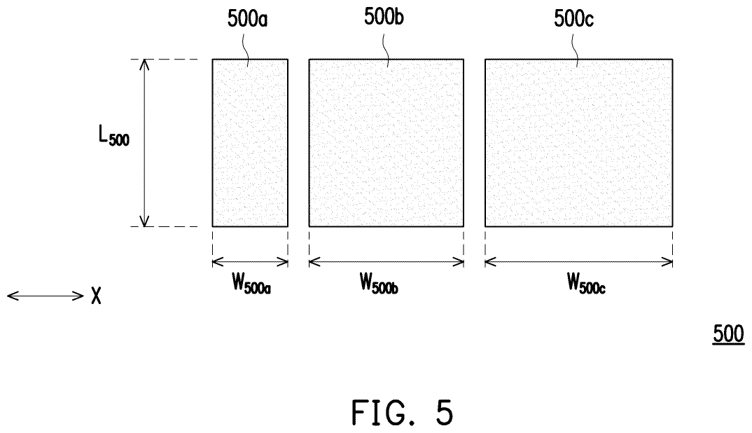

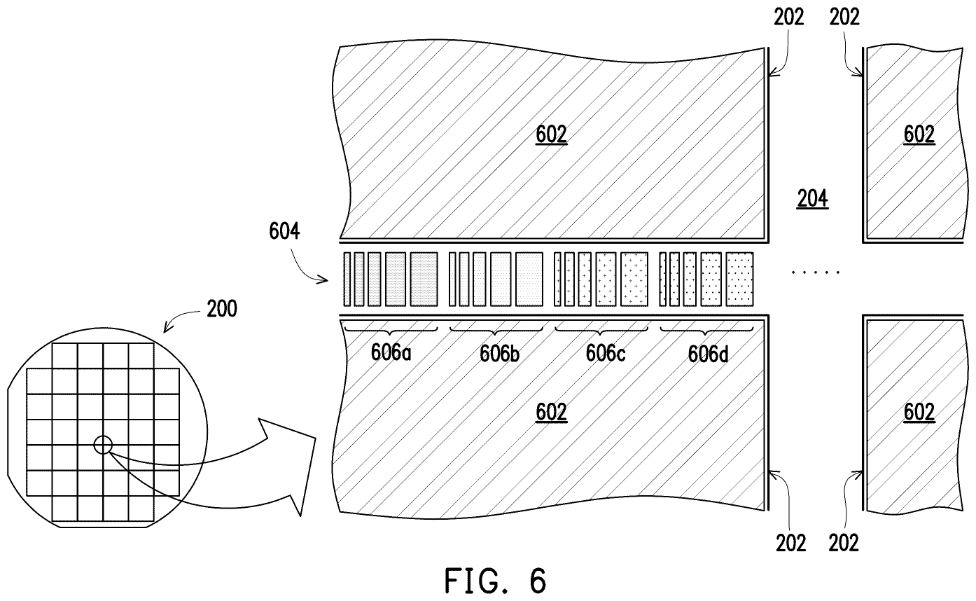

Referring to FIG. 1, at a step S106, the layout optimization test group is obtained according to the adjusted patterns. In the illustrated embodiments (as shown in FIG. 6), the layout optimization test group includes a first cluster of test pattern arrays 606a formed by replacing some repetitive pattern elements in the first layout pattern into a plurality of the adjusted patterns 400a, a second cluster of test pattern arrays 606b formed by replacing some repetitive pattern elements in the first layout pattern into a plurality of the adjusted patterns 400b, a third cluster of test pattern arrays 606c formed by replacing some repetitive pattern elements in the first layout pattern into a plurality of the adjusted patterns 400c, and a fourth cluster of test pattern arrays 606d formed by replacing some repetitive pattern elements in the first layout pattern into a plurality of the adjusted patterns (not shown). As shown in FIG. 6 (but not limited to), each of the first cluster of test pattern arrays 606a, the second cluster of test pattern arrays 606b, the third cluster of test pattern arrays 606c and the fourth cluster of test pattern arrays 606d includes five test pattern arrays with different capacity, but the invention is not limited thereto. As shown in FIG. 5, each cluster of test pattern arrays includes test pattern arrays 500a with a first capacity, test pattern arrays 500b with a second capacity and test pattern arrays 500c with a third capacity. In the illustrated embodiments, the repetitive pattern elements are arranged by a reference pitch in the first layout pattern. In the first cluster of test pattern arrays 606a, the adjusted patterns 400a are arranged by the reference pitch, in the second cluster of test pattern arrays 606b, the adjusted patterns 400b are arranged by the reference pitch, and so on and so forth. The afore-described capacity may, for example, indicate an amount of the lines 302. In the illustrated embodiments, the first capacity may be 1 MB, the second capacity may be 2 MB and the third capacity may be 4 MB. Nevertheless, the present disclosure is not limited to these capacities nor the amount of the test pattern arrays, as long as each cluster of test pattern arrays includes test pattern arrays formed by the same pattern but having different capacities. According to a preferred embodiment, in each cluster of test pattern arrays, the smallest capacity may be 1 MB, and the largest capacity may be identical with total capacity in one of the chip regions (such as 1 GB). In another preferred embodiment, a ratio of the capacity of each test pattern array with respect to total memory capacity of the memory array formed in one of the chip regions lies in a range from 0.05% to 2%.

FIG. 5 is a schematic plan view illustrating a cluster of test pattern arrays 500 for one of the adjustment schemes. As having different capacity, test pattern arrays 500a, 500b, 500c in the cluster of test pattern arrays 500 have different widths (along the direction X) W₅₀₀ₐ, W_{500b} and W_{500c}. The width W_{500c} is greater than the width W_{500b}, and the width W_{500b} is greater than the width W₅₀₀ₐ. On the other hand, the test pattern arrays 500a, 500b, 500c may have substantially identical length L₅₀₀ (along an extending direction of the lines 302).

Referring to FIG. 1 and FIG. 6, at a step S108, a lithography process or a combination of a lithography process and an etching process is performed to form the layout optimization test group 604 in the scribe line region 204 of the wafer 200. In one embodiment, a first layout pattern including any of the test pattern arrays can also be formed in the chip regions 202 of the wafer 200 while forming the layout optimization test group 604.

At a following step S110, an electrical inspection is performed on the test pattern arrays formed on the wafer 200, and a best manufacturing solution is selected from the clusters of test pattern arrays 606a, 606b, 606c, 606d according to a result of the electrical inspection. In the embodiments where the wafer is formed with multiple layout optimization test groups targeting different lithography hotspots, a best manufacturing solution corresponding to each lithography hotspot may be selected according to the result of the electrical inspection performed on the corresponding layout optimization test group. According to some embodiments, the electrical inspection is performed on the clusters of test pattern arrays formed on the wafer 200 before completing manufacturing of the wafer 200 (e.g., before completing layers over the first layout pattern). As an example, the electrical inspection is a wafer acceptance test (WAT). The testing apparatus operated to perform the electrical inspection may output trend lines each indicating the inspection result of one of the clusters of test pattern arrays. By analyzing the trend lines, an idealist one of the trend lines can be selected, and the adjusted pattern in the cluster of test pattern arrays corresponding to the idealist trend line is determined as the best manufacturing solution.

According to some embodiments, each trend line indicates a relationship between WAT test result (i.e., yield) and capacity of the test pattern arrays in one of the clusters of test pattern arrays 606a, 606b, 606c, 606d. Among these trend lines, the one indicating least yield variation with respect to varying capacity or the one indicating that even the lowest yield does not fall below a predetermined level can be selected as the idealist one, and the corresponding adjusted pattern can be determined as the best manufacturing solution.

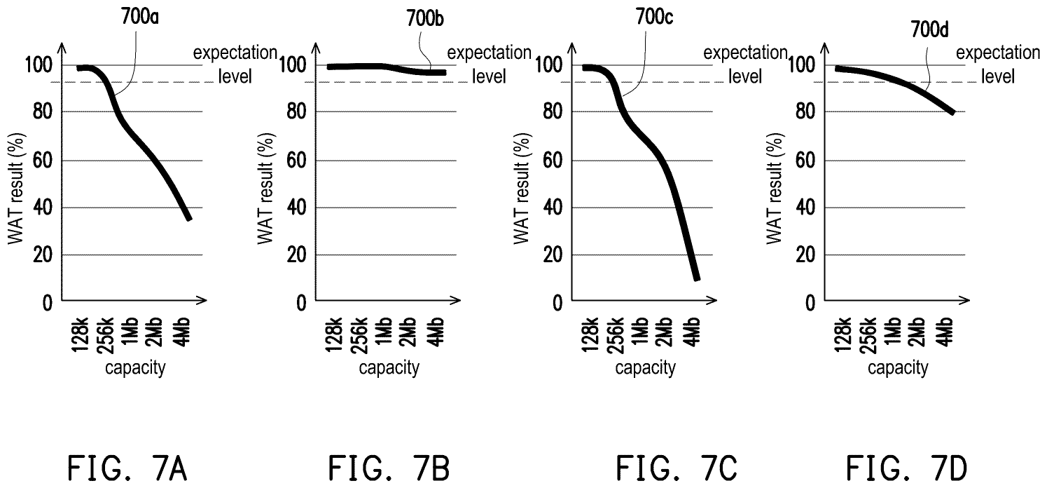

Trend lines for the first cluster of test pattern arrays 606a, the second cluster of test pattern arrays 606b, the third cluster of test pattern arrays 606c and the fourth cluster of test pattern arrays 606d are shown in graphs of FIG. 7A through FIG. 7D. A vertical axis of each graph indicates WAT result (i.e., yield %), and a lateral axis of each graph indicates capacity of the test pattern arrays (equivalently measured by megabytes (MB)). An electrical trend line 700a shows WAT results of all test pattern arrays in the first cluster of test pattern arrays 606a; an electrical trend line 700b shows WAT results of all test pattern arrays in the second cluster of test pattern arrays 606b; an electrical trend line 700c shows WAT results of all test pattern arrays in the third cluster of test pattern arrays 606c; and an electrical trend line 700d shows WAT results of all test pattern arrays in the fourth cluster of test pattern arrays 606d. Among the electrical trend lines 700a, 700b, 700c, 700d, the electrical trend line 700b shows least yield variation with respect to increasing capacity, and is entirely above an expected level. Therefore, the adjusted pattern 400b in the second cluster of test pattern arrays 606b corresponding to the electrical trend line 700b is determined as the best manufacturing solution.

Referring to FIG. 1, at a step S112, the first layout pattern is modified according to the best manufacturing solution, to form a second layout pattern. The second layout pattern is qualified for mass production, and can be formed in chip regions of a wafer for mass production. In those embodiments where the first layout pattern has two lithography hotspots (e.g., the featured array pattern 300a and the features array pattern 300b), clusters of test pattern arrays for the featured array pattern 300a and clusters of test pattern arrays for the featured array pattern 300b may be generated at the step S106. In certain case, the decision made in the step S110 might indicate that the featured array pattern 300a should be modified by the adjusted pattern 400b, whereas the featured array pattern 300b should not require modification. Under such assumption, the second layout pattern might be obtained by merely modifying the featured array pattern 300a in the first layout pattern by the adjusted pattern 400b. Specifically, the extending portion 302e in the adjusted pattern 400b may be used for replacing the extending portions 302e extending from some of the lines 302 in the featured array pattern 300a. As portions of the first layout pattern that may cause difficulties in lithography have been modified according to qualified pattern optimization option, the first layout pattern is optimized. That is, such replacement operation can be applied to one or more lithography hotspot(s) in the first layout pattern, to obtain the qualified second layout pattern.

The above-described optimization method may be used for layout pattern in any pattern layer of an integrated circuit, and the optimized layout pattern (i.e., the second layout pattern) takes place of original layout pattern (i.e., the first layout pattern) for being transferred to wafer. Since lithography hotspots in the original layout pattern have been removed, the integrated circuit can be manufactured with improved yield.

As above, the method for optimizing layout pattern according to embodiments of the present disclosure includes generating adjusted patterns corresponding to a first layout pattern; generating clusters of test pattern arrays based on the adjusted patterns; and determining a best manufacturing solution among the adjusted patterns according to result of an electrical inspection performed on each test pattern array. Accordingly, a second layout pattern (i.e., an optimized and qualified layout pattern) can be determined based on the best manufacturing solution. As compared to relying on experience to adjust layout pattern and modifying layout pattern via trial-and-error manner, the optimizing process for layout pattern provided in the present disclosure is much shorter in time, and yield can be improved. Further, when manufacturing process is adjusted, whether if the current layout pattern needs to be modified can be determined by placing a layout optimization test group in a scribe line region of a wafer and executing electrical inspection on the layout optimization test group. In this way, development of a new process can be shortened. Further, in some embodiments, the electrical inspection performed on the layout optimization test group does not have to wait until entire wafer process is finished. Instead, the electrical inspection can be performed right after formation of the layout optimization test group. Therefore, the test result can be more indicative, and a shorter layout pattern optimization process can be resulted.

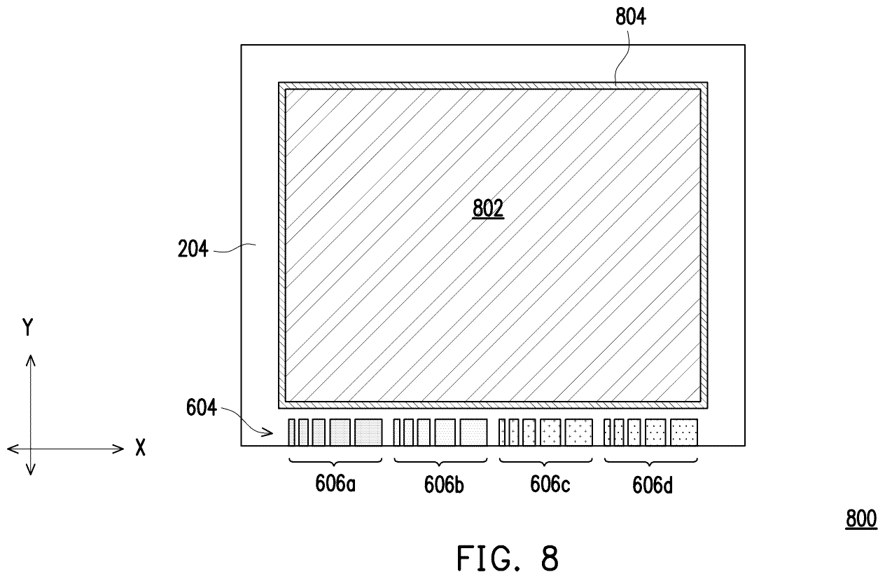

FIG. 8 is a schematic plan view illustrating a semiconductor chip 200 singulated from the wafer 200, according to some embodiments of the present disclosure.

Referring to FIG. 8, the semiconductor chip 800 includes a second layout pattern 802, and may further include a seal ring 804. The seal ring 804 may surround the second layout pattern 802, and may protect the second layout pattern 802 during singulation. In some embodiments, the seal ring 804 may be formed of a metallic material. In some embodiments, the scribe line region 204 of the wafer 200 partially remains in the semiconductor chip 800, and the remained portion of the scribe line region 204 may be located aside the seal ring 804. In these embodiments, at least one layout optimization test group (e.g., the layout optimization test group 604) formed in the scribe line region 204 may partially remain in the remained portion of the scribe line region 204. As an example, an upper half of the layout optimization test group 604 is remained in the semiconductor chip 800. The remained portion of the layout optimization test group 604 may include portions of the first cluster of test pattern arrays 606a, the second cluster of test pattern arrays 606b, the third cluster of test pattern arrays 606c and the fourth cluster of test pattern arrays 606d. The test pattern arrays in each cluster are separately arranged side-by-side, and may be arranged in an order from smallest capacity to greatest capacity (or vice versa). Moreover, the test pattern arrays are identical with one another in terms of length, but are different from one another in terms of width (as having different capacity).

The method for optimizing layout pattern according to the present disclosure may effectively shorten product development process, and increase manufacturing yield. Therefore, less wafer resource is required for the product development process, and the product development process is more resource efficient. Accordingly, the present invention can avoid wasting resources, so as to provide a green semiconductor technology.

As described, the layout optimization test group 604 may be partially remained in the singulated semiconductor chip 800. However, in alternative embodiments, the layout optimization test group 604 may not remain in the remained portions of the scribe line region 204 in the singulated semiconductor chip 800. In further embodiments, the scribe line region 204 may even be absent in the singulated semiconductor chip 800.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for optimizing layout pattern, comprising:
generating adjusted patterns corresponding to a first layout pattern;
generating a layout optimization test group according to the adjusted patterns, wherein the layout optimization test group comprises a first cluster of test pattern arrays and a second cluster of test pattern arrays, the first cluster of test pattern arrays comprise first test pattern arrays in accordance with one of the adjusted patterns and different from one another in terms of capacity, and the second cluster of test pattern arrays comprise second test pattern arrays in accordance with another one of the adjusted patterns and different from one another in terms of capacity;
forming the layout optimization test group on a wafer;
performing an electrical inspection on the first test pattern arrays and the second test pattern arrays, and determining a best manufacturing solution from the adjusted patterns according to a result of the electrical inspection; and
determining a second layout pattern to be formed on chip regions of the wafer according to the best manufacturing solution.

2. The method for optimizing layout pattern according to claim 1, wherein the first layout pattern includes repetitive pattern elements, and generating a layout optimization test group according to the adjusted patterns including replacing a portion of the repetitive pattern elements with the adjusted patterns.

3. The method for optimizing layout pattern according to claim 2, wherein the portion of the repetitive pattern elements are respectively an extending portion of a line pattern, a width of the extending portion is greater than a width of a body portion of the line pattern.

4. The method for optimizing layout pattern according to claim 3,
wherein the adjusted patterns comprise a first adjusted pattern and a second adjusted pattern, a length-to-width ratio of the first adjusted pattern is different from a length-to-width ratio of the second adjusted pattern,
wherein the first test pattern arrays are generated in accordance with the first adjusted pattern, and the second test pattern arrays are generated in accordance with the second adjusted pattern,
wherein the best manufacturing solution is selected among the first adjusted pattern and the second adjusted pattern according to the result of the electrical inspection.

5. The method for optimizing layout pattern according to claim 3, wherein in each of the first test pattern arrays, a length of each of the adjusted patterns is different from a length of the extending portion.

6. The method for optimizing layout pattern according to claim 1, wherein a ratio of the capacity of each of the test pattern arrays with respect to a total memory capacity of a memory array formed in one of the chip regions lies in a range from 0.05% to 2%.

7. The method for optimizing layout pattern according to claim 4, wherein the first adjusted pattern and the second adjusted pattern have identical length and different widths.

8. The method for optimizing layout pattern according to claim 1, wherein the layout optimization test group is formed in a scribe line region of the wafer by a lithography process, the first test pattern arrays are separately arranged side-by-side, and the second test pattern arrays are separately arranged side-by-side.

9. The method for optimizing layout pattern according to claim 1, further comprising:
obtaining a first electrical trend line corresponding to the first cluster of test pattern arrays and a second electrical trend line corresponding to the second cluster of test pattern arrays by performing the electrical inspection; and
determining whether the first electrical trend line and the second electrical trend line fulfill expectation,
wherein determining the best manufacturing solution from the adjusted patterns according to the result of the electrical inspection comprises determining the adjusted pattern corresponding to one of the first electrical trend line and the second electrical trend line that fulfills expectation, to be the best manufacturing solution.

10. The method for optimizing layout pattern according to claim 9, wherein the electrical inspection is a wafer acceptance test (WAT).

11. The method for optimizing layout pattern according to claim 10, wherein each of the first electrical trend line and the second electrical trend line indicates a relationship between a result of the WAT with respect to the capacity.

12. The method for optimizing layout pattern according to claim 9, wherein determining whether the first electrical trend line and the second electrical trend line fulfill expectation comprises determining variation of each of the first electrical trend line and the second electrical trend line, or determining whether the first electrical trend line and the second electrical trend line are entirely lies above an expectation level.

13. A semiconductor wafer, comprising:
an integrated circuit, formed in a chip region; and
a layout optimization test group, formed in a scribe line region, wherein the layout optimization group comprises a first cluster of test pattern arrays and a second cluster of test pattern arrays, the first cluster of test pattern arrays comprises first test pattern arrays in accordance with a first adjusted pattern and different from one another in terms of capacity, and the second cluster of test pattern arrays comprises second test pattern arrays in accordance with a second adjusted pattern and different with one another in terms of capacity.

14. The semiconductor wafer according to claim 13, wherein a length-to-width ratio of the first adjusted pattern is different from a length-to-width ratio of the second adjusted pattern.

15. The semiconductor wafer according to claim 13, wherein the first test pattern arrays are separately arranged side-by-side, and the second test pattern arrays are separately arranged side-by-side.
